(19) United States
(12) Patent Application Publication
(10) Pub. No.: US 2022/0254874 A1
(43) Pub. Date: Aug. 11, 2022

(54) SEMICONDUCTOR STRUCTURE AND METHOD FOR FORMING SAME

(71) Applicant: CHANGXIN MEMORY TECHNOLOGIES, INC., Hefei City (CN)

(72) Inventors: Er-Xuan PING, Hefei City (CN); Zhen ZHOU, Hefei City (CN); Weiping BAI, Hefei City (CN); Mengkang YU, Hefei City (CN); Xingsong SU, Hefei City (CN)

(73) Assignee: CHANGXIN MEMORY TECHNOLOGIES, INC., Hefei City (CN)

(21) Appl. No.: 17/648,666

(22) Filed: Jan. 21, 2022

Related U.S. Application Data
(63) Continuation of application No. PCT/CN2021/120205, filed on Sep. 24, 2021.

(30) Foreign Application Priority Data
Feb. 5, 2021 (CN) 202110163948.9

(51) Int. Cl. H01L 49/02; H01L 27/108

(52) U.S. Cl. CPC H01L 28/92; H01L 27/10805; H01L 28/88

(57) ABSTRACT

A method for forming a semiconductor structure can include the following steps. A substrate and an insulating layer that are stacked are provided, the substrate having a plurality of storage node contact structures spaced apart from each other. A grid-like upper electrode layer is formed on a surface of the insulating layer, where the upper electrode layer has a plurality of meshes penetrating the upper electrode layer, and an orthographic projection of each of the meshes on the insulating layer and an orthographic projection of a storage node contact structure on the insulating layer have an overlapping area. A dielectric layer is formed on a side wall of each mesh. The insulating layer exposed from the mesh is removed to expose the storage node contact structure. A lower electrode layer is formed inside each mesh.

### CROSS-REFERENCE TO RELATED APPLICATIONS

This is a continuation of International Patent Application No. PCT/CN2021/120205 filed on Sep. 24, 2021, which claims priority to Chinese Patent Application No. 202110163948.9 filed on Feb. 5, 2021. The disclosures of the above-referenced applications are hereby incorporated by reference in their entirety.

### BACKGROUND

Dynamic Random Access Memory (DRAM) is a semiconductor memory device commonly used in computers, which consists of many repetitive memory cells. Each memory cell includes a capacitor and a transistor. Enough capacitance is the basic requirement to ensure the normal operation of the DRAM and enough storage time. In the DRAM process, the DRAM adopts the stacked capacitor structure. At present, the capacitor of the DRAM cell adopts hexagonal honeycomb layout, and the capacitor is a cylindrical or columnar structure with a large aspect ratio.

### SUMMARY

The embodiments of the present disclosure relate to but are not limited to a semiconductor structure and a method for forming the same.

According to a first aspect of the embodiments of the present disclosure, there is provided a method for forming a semiconductor structure which includes the following steps. A substrate and an insulating layer that are stacked are provided, the substrate having a plurality of storage node contact structures spaced apart from each other. A grid-like upper electrode layer is formed on a surface of the insulating layer, where the upper electrode layer has a plurality of meshes penetrating the upper electrode layer, and an orthographic projection of each of the meshes on the insulating layer and an orthographic projection of the storage node contact structure on the insulating layer have an overlapping area. A dielectric layer is formed on a side wall of each mesh. The insulating layer exposed from the mesh is removed to expose the storage node contact structure. A lower electrode layer is formed inside each mesh, where the lower electrode layer is located on a side of the dielectric layer away from the upper electrode layer, and is also in contact with the exposed storage node contact structure, and the lower electrode layers in different meshes are electrically insulated from each other.

According to a second aspect of the embodiments of the present disclosure, there is further provided a semiconductor structure. The semiconductor structure includes: a substrate and an insulating layer that are stacked, where the substrate has a plurality of storage node contact structures spaced apart from each other and the insulating layer exposes the storage node contact structures; a grid-like upper electrode layer that is located on a surface of the insulating layer and has a plurality of meshes penetrating the upper electrode layer, where each of the meshes exposes the storage node contact structure; a dielectric layer located on a side wall of each mesh; and a lower electrode layer located inside each mesh, located on a side of the dielectric layer away from the upper electrode layer, and also in contact with the exposed storage node contact structure, where the lower electrode layers in different meshes are electrically insulated from each other.

### BRIEF DESCRIPTION OF THE DRAWINGS

One or more embodiments are illustrated by the corresponding figures in the accompanying drawings, which does not constitute a limitation on the embodiments. Unless specifically stated, the figures in the drawings do not constitute a scale limitation.

FIG. 1 illustrates a first schematic diagram of a step in a method for forming a semiconductor structure according to a first embodiment of the present disclosure.

FIG. 2 illustrates a second schematic diagram of a step in a method for forming a semiconductor structure according to a first embodiment of the present disclosure.

FIG. 3 illustrates a third schematic diagram of a step in a method for forming a semiconductor structure according to a first embodiment of the present disclosure.

FIG. 4 illustrates a fourth schematic diagram of a step in a method for forming a semiconductor structure according to a first embodiment of the present disclosure.

FIG. 5 illustrates a fifth schematic diagram of a step in a method for forming a semiconductor structure according to a first embodiment of the present disclosure.

FIG. 6 illustrates a sixth schematic diagram of a step in a method for forming a semiconductor structure according to a first embodiment of the present disclosure.

FIG. 7 illustrates a seventh schematic diagram of a step in a method for forming a semiconductor structure according to a first embodiment of the present disclosure.

FIG. 8 illustrates an eighth schematic diagram of a step in a method for forming a semiconductor structure according to a first embodiment of the present disclosure.

FIG. 9 illustrates a ninth schematic diagram of a step in a method for forming a semiconductor structure according to a first embodiment of the present disclosure.

FIG. 10 illustrates a tenth schematic diagram of a step in a method for forming a semiconductor structure according to a first embodiment of the present disclosure.

FIG. 11 illustrates an eleventh schematic diagram of a step in a method for forming a semiconductor structure according to a first embodiment of the present disclosure.

FIG. 12 illustrates a twelfth schematic diagram of a step in a method for forming a semiconductor structure according to a first embodiment of the present disclosure.

FIG. 13 illustrates a thirteenth schematic diagram of a step in a method for forming a semiconductor structure according to a first embodiment of the present disclosure.

FIG. 14 illustrates a fourteenth schematic diagram of a step in a method for forming a semiconductor structure according to a first embodiment of the present disclosure.

FIG. 15 illustrates a fifteenth schematic diagram of a step in a method for forming a semiconductor structure according to a first embodiment of the present disclosure.

FIG. 16 illustrates a sixteenth schematic diagram of a step in a method for forming a semiconductor structure according to a first embodiment of the present disclosure.

FIG. 17 illustrates a seventeenth schematic diagram of a step in a method for forming a semiconductor structure according to a first embodiment of the present disclosure.

FIG. 18 illustrates an eighteenth schematic diagram of a step in a method for forming a semiconductor structure according to a first embodiment of the present disclosure.

FIG. 19 illustrates a nineteenth schematic diagram of a step in a method for forming a semiconductor structure according to a first embodiment of the present disclosure.

FIG. 20 illustrates a twentieth schematic diagram of a step in a method for forming a semiconductor structure according to a first embodiment of the present disclosure.

FIG. 21 illustrates a first schematic diagram of a step in a method for forming a semiconductor structure according to a second embodiment of the present disclosure.

FIG. 22 illustrates a second schematic diagram of a step in a method for forming a semiconductor structure according to a second embodiment of the present disclosure.

FIG. 23 illustrates a third schematic diagram of a step in a method for forming a semiconductor structure according to a second embodiment of the present disclosure.

FIG. 24 illustrates a fourth schematic diagram of a step in a method for forming a semiconductor structure according to a second embodiment of the present disclosure.

FIG. 25 illustrates a fifth schematic diagram of a step in a method for forming a semiconductor structure according to a second embodiment of the present disclosure.

FIG. 26 illustrates a sixth schematic diagram of a step in a method for forming a semiconductor structure according to a second embodiment of the present disclosure.

FIG. 27 illustrates a seventh schematic diagram of a step in a method for forming a semiconductor structure according to a second embodiment of the present disclosure.

FIG. 28 illustrates an eighth schematic diagram of a step in a method for forming a semiconductor structure according to a second embodiment of the present disclosure.

FIG. 29 illustrates a ninth schematic diagram of a step in a method for forming a semiconductor structure according to a second embodiment of the present disclosure.

FIG. 30 illustrates a tenth schematic diagram of a step in a method for forming a semiconductor structure according to a second embodiment of the present disclosure.

FIG. 31 illustrates a schematic diagram of a semiconductor structure according to a third embodiment of the present disclosure.

FIG. 32 illustrates a schematic diagram of another semiconductor structure according to a third embodiment of the present disclosure.

FIG. 33 illustrates a schematic diagram of still another semiconductor structure according to a third embodiment of the present disclosure.

FIG. 34 illustrates a schematic diagram of yet another semiconductor structure according to a third embodiment of the present disclosure.

### DETAILED DESCRIPTION

The electrode plate of the capacitor of the semiconductor structure typically has a small area.

The current capacitor layout structure causes the pitch ratio of the word line and the bit line to be fixed to about 1.5, and the fixed pitch ratio of the word line to bit line restricts the diversity of the DRAM process. The inventors of the present disclosure have recognized that how to increase the area of the capacitor electrode plate as much as possible while not limiting the pitch ratio of the word line to bit line in the DRAM is a technical problem to be solved.

The capacitor of the semiconductor structure adopts hexagonal honeycomb layout, and the capacitor is cylindrical or columnar structure with maximum aspect ratio. The hexagonal honeycomb layout causes the pitch ratio of word line and bit line of semiconductor structure to be fixed to about 1.5, and the fixed pitch ratio of word line to bit line restricts the variety of semiconductor structure process. When forming a columnar or cylindrical capacitor with a maximum depth-width ratio, in order to prevent the capacitor from collapsing due to an excessive depth-width ratio, it is necessary to form a supporting layer first, and then remove the supporting layer after forming the capacitor. Such a forming method is tedious in process and wastes materials, and the process cost is high. Because the hexagonal honeycomb layout of the capacitor cannot completely cover the rectangular word-bit line structure, the electrode plate area of the capacitor is not maximized under the given word-bit line pitch ratio.

In order to solve the above problems, the embodiments of the present disclosure provide a method for forming a semiconductor structure. An upper electrode layer formed is an interconnected grid-like structure, and the structure is stable, so that a problem of capacitor structure collapse can be effectively avoided. Due to the fact that the natural dense row of grid-like upper electrode layer completely covers the rectangular word-bit line structure, the area of the capacitor electrode plate is maximized under the given word-bit line pitch ratio, which improves the performance of the semiconductor structure.

In order to make the objectives, technical solutions and advantages of the embodiments of the present disclosure clearer, the following describes the embodiments of the present disclosure in detail with reference to the accompanying drawings. However, those of ordinary skill in the art may understand that in various embodiments of the present disclosure, many technical details are proposed for the reader to better understand the present disclosure. However, even without these technical details and various changes and modifications according to the following embodiments, the technical solutions claimed in the present disclosure may be realized.

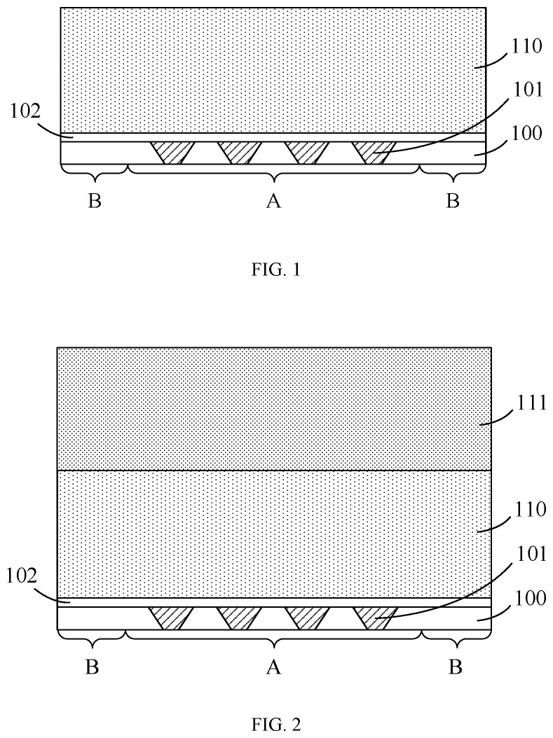

FIGS. 1-20 illustrate corresponding schematic diagrams of various steps in a method for forming a semiconductor structure according to a first embodiment of the present disclosure.

Referring to FIG. 1, the semiconductor structure includes a capacitor region A and a peripheral region B located at the periphery of the capacitor region A. A substrate 100 and an insulating layer 102 which are stacked are provided, the substrate 100 and the insulating layer 102 are located in the capacitor region A and the peripheral region B.

The material of the substrate 100 is a semiconductor material. In this embodiment, the material of the substrate 100 is silicon. In other embodiments, the substrate may also be a germanium substrate, a silicon germanium substrate, a silicon carbide substrate, or a silicon-on-insulator substrate.

The substrate 100 has a plurality of storage node contact structures 101 spaced apart from each other, the storage node contact structures 101 are located in the capacitor region A, and the storage node contact structures 101 are used to connect transistors and capacitors in the semiconductor structure.

The material of the storage node contact structure 101 is metal. In this embodiment, the material of the storage node contact structure 101 may be tungsten metal. In other embodiments, the material of the storage node contact structure may be copper metal, aluminum metal, gold metal, silver metal, or the like.

The insulating layer 102 functions as an insulating protection. In this embodiment, the material of the insulating layer 102 is silicon oxide. In other embodiments, the material of the insulating layer 102 may be a high-K material.

Subsequently, a grid-like upper electrode layer needs to be formed on the surface of the insulating layer 102, and the steps of forming the grid-like upper electrode layer will be described in detail below with reference to the accompanying drawings.

Referring to FIG. 1, a model layer 110 is formed on the surface of the insulating layer 102 by a chemical vapor deposition process, and the model layer 110 completely covers the insulating layer 102.

Referring to FIG. 2, a mask layer 111 is formed on the surface of the model layer 110 using a chemical vapor deposition process.

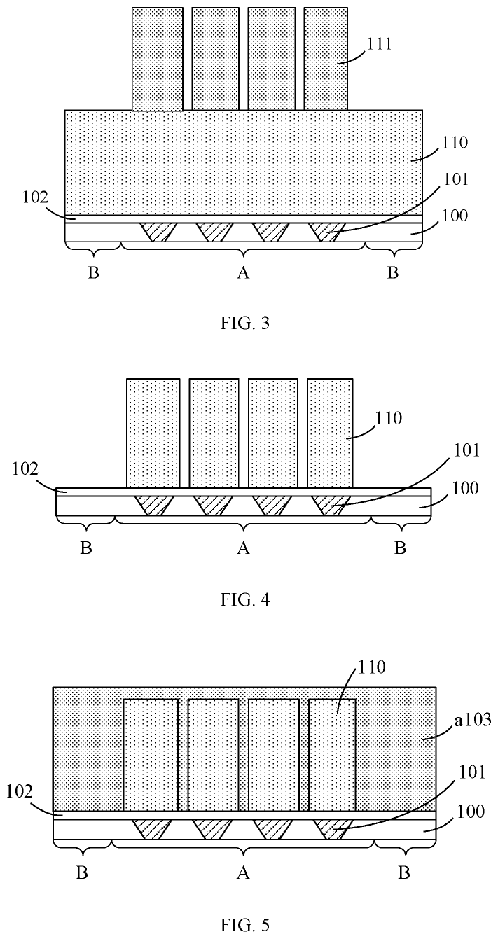

Referring to FIG. 3, a double-layer patterning process is used so that the mask layer 111 has a plurality of openings penetrating the mask layer 111, and the orthographic projection of the opening on the insulating layer 102 does not overlap with the orthographic projection of the storage node contact structure 101 on the insulating layer 102. In other embodiments, a four-times patterning process or an extreme ultraviolet photolithography process may be used to form the openings.

Referring to FIG. 4, a double-layer patterning process is used so that the shape of the model layer 110 is exactly the same as that of the patterned mask layer 111 (referring to FIG. 3). The model layer 110 has a plurality of openings penetrating the model layer 110, the orthographic projection of the opening on the insulating layer 102 does not overlap the orthographic projection of the storage node contact structure 101 on the insulating layer 102, and the mask layer 111 is removed.

Referring to FIG. 5, an initial upper electrode layer a103 fully filling openings is formed using an atomic layer deposition process, and the top surface of the initial upper electrode layer a103 is higher than the top surface of the model layer 110.

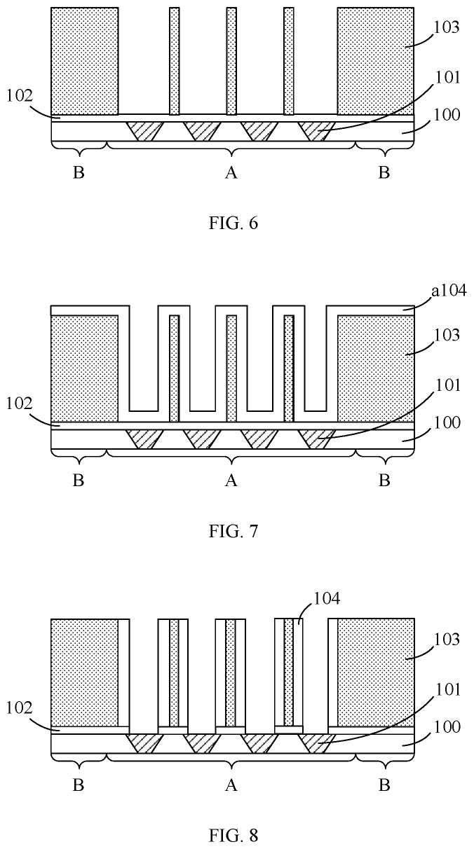

Referring to FIG. 6, a portion of the initial upper electrode layer a103 (referring to FIG. 5) is removed by chemical mechanical polishing process so that the top surface of the remaining initial upper electrode layer a103 is flush with the top surface of the model layer 110 (referring to FIG. 5), and the remaining initial upper electrode layer a103 is served as the upper electrode layer 103. The model layer 110 is removed using a wet etch process.

As such, a grid-like upper electrode layer 103 is formed on the surface of the insulating layer 102. The upper electrode layer 103 has a plurality of meshes penetrating the upper electrode layer 103. The orthographic projection of each of the meshes on the insulating layer 102 and the orthographic projection of a storage node contact structure 101 on the insulating layer 102 have an overlapping region. The meshes are located in the capacitor region A, and the upper electrode layer 103 is located not only in the capacitor region A but also in the peripheral region B.

Since word lines and bit lines of the semiconductor structure are regularly arranged in columns and rows, and a plurality of storage node contact structures 101 are arranged in a regular quadrangle, the grid-like upper electrode layer 103 facing the storage node contact structures 101 thus is a rectangular grid.

The upper electrode layer 103 may be a conductive material or may be composed of a plurality of conductive materials, such as doped polysilicon, titanium, titanium nitride, tungsten, and tungsten composites. In this embodiment, the upper electrode layer 103 is made of tungsten material.

A grid-like upper electrode layer 103 is formed where a plurality of meshes penetrating the upper electrode layer 103 face each storage node contact structure 101. Since the grid-like upper electrode layer 103 facing the storage node contact structure 101 realizes natural dense arrangement, the pitch ratio of the word line and the bit line does not need to be fixed, which is conducive to reducing limitations and difficulties in structural design and material requirements of the semiconductor structure. Moreover, the natural dense arrangement of the upper electrode layer 103 maximizes the electrode plate area of the capacitor under a predetermined word-bit line pitch ratio. Since the upper electrode layer 103 is grid-like, which indicates that the upper electrode layers 103 are connected to each other and form a solid whole, the problem of capacitor structure collapse is effectively avoided.

Referring to FIG. 7, a dielectric film a104 is formed on the side wall of the mesh, top surface of the upper electrode layer 103, and the surface of the insulating layer 102 exposed from the mesh.

The material of the dielectric film a104 is a high dielectric constant material, for example high dielectric constant elements such as Hf, La, Ti, and Zr or oxides thereof, and Si and N dopants may be used. The dielectric layer is subsequently formed on the basis of the dielectric film a104.

In this embodiment, the dielectric film a104 is formed by the atomic layer deposition process, and the dielectric film a104 formed by the atomic layer deposition process has good coverage. In other embodiments, a chemical vapor deposition process may also be used to form the dielectric film.

Referring to FIG. 8, the dielectric film a104 located on the top surface of the upper electrode layer 103 and the surface of the insulating layer 102 exposed from the mesh is removed by a dry etching process (referring to FIG. 7) so that the remaining dielectric film a104 is located only on both sides of the mesh, and the remaining dielectric film a104 is served as the dielectric layer 104.

The insulating layer 102 exposed from the mesh is removed by a dry etching process to expose the storage node contact structure 101. Subsequently, a lower electrode layer needs to be formed on the exposed storage node contact structure 101 surface.

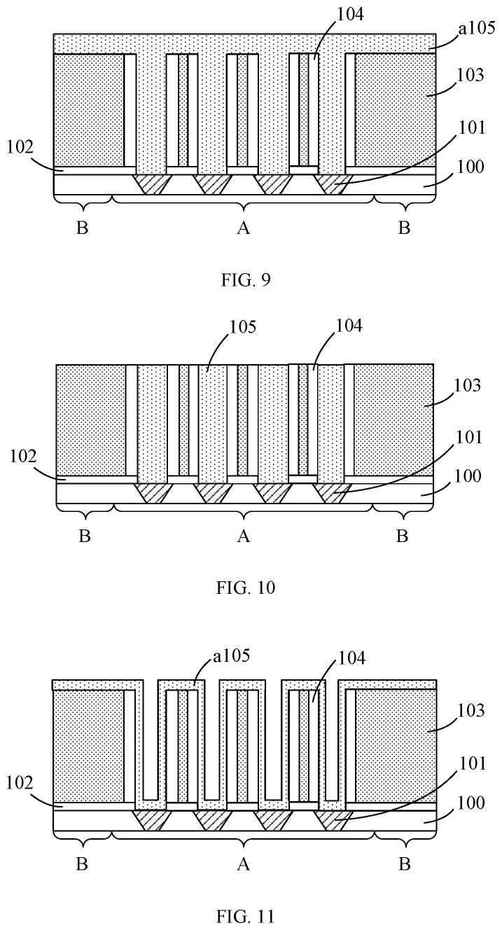

Referring to FIG. 9, in this embodiment, a lower electrode film a105 is formed, the lower electrode film a105 is located inside the mesh, the side of the dielectric layer 104 away from the upper electrode layer 103 and the exposed surface of the storage node contact structure 101, and is also located on the upper surface of the dielectric layer 104 and the upper surface of the upper electrode layer 103.

In this embodiment, the lower electrode film a105 is formed by using the chemical vapor deposition process. Usage of the chemical vapor deposition process for forming the lower electrode film a 105 accelerates the formation rate and improves the formation efficiency of the semiconductor structure. In other embodiments, an atomic layer deposition process may be used to form the lower electrode film.

The lower electrode film a105 may be a conductive material or may be made of a plurality of conductive materials, such as doped polysilicon, titanium, titanium nitride, tungsten, and tungsten composites. In this embodiment, the lower electrode film a105 is made of titanium nitride. Subsequently, the lower electrode layer 105 is formed on the basis of the lower electrode film a105.

Referring to FIG. 10, a planarization process is used to remove the lower electrode film a105 (referring to FIG. 9) located on the upper surface of the dielectric layer 104 and the upper surface of the upper electrode layer 103. The remaining lower electrode film a105 is served as the lower electrode layer 105, and the lower electrode layer 105 fully fills the mesh. The formed lower electrode layer 105 is located on the side of the dielectric layer 104 away from the upper electrode layer 103, and is also in contact with the exposed storage node contact structure 101. The lower electrode layers 105 in different meshes are electrically insulated from each other.

The used planarization process is a chemical mechanical polishing process. The chemical mechanical polishing process not only removes the lower electrode film a105 located on the upper surface of the dielectric layer 104 and the upper surface of the upper electrode layer 103, so that the lower electrode layers 105 in the different meshes are electrically insulated from each other, but also makes the upper surface of the lower electrode layer 105 more flat.

Referring to FIG. 11, in other embodiments, the lower electrode film a105 is formed, and the lower electrode film a105 is located inside the mesh, on the side of the dielectric layer 104 away from the upper electrode layer 103, and on the exposed surface of the storage node contact structure 101, and also is located on the upper surface of the dielectric layer 104 and the upper surface of the upper electrode layer 103. Moreover, the lower electrode film a105 inside each mesh encircles and forms a through via.

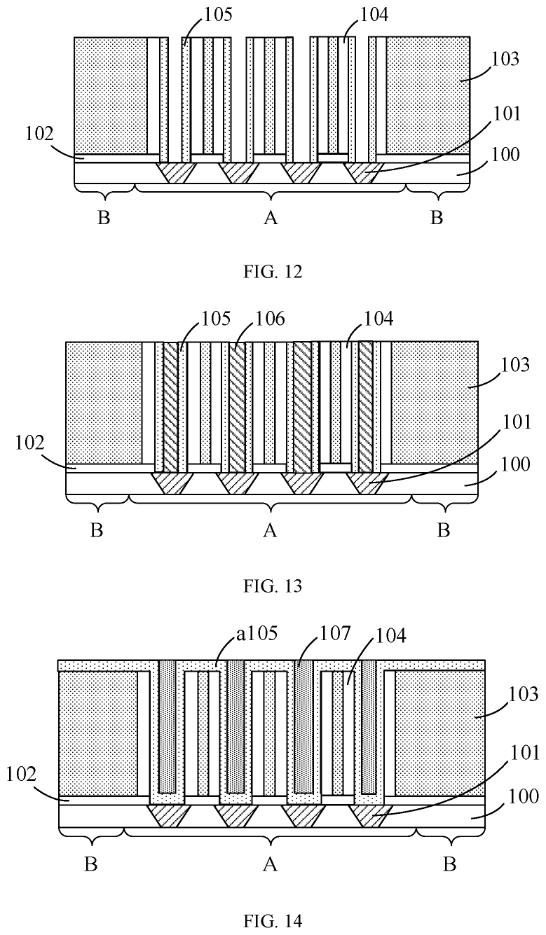

Referring to FIG. 12, the lower electrode film a105 located on the upper surface of the dielectric layer 104 and the upper surface of the upper electrode layer 103 is etched and removed by a dry etching process (referring to FIG. 11), and a portion of the lower electrode film a105 located at the bottom of the through via is also etched and removed, and the remaining lower electrode film a105 is served as the lower electrode layer.

Referring to FIG. 13, after the lower electrode layer 105 is formed, a conductive filling layer 106 is formed in each grid, and the conductive filling layer 106 fully fills the through via, and the conductive filling layer 106 is in contact with the storage node contact structure 101 exposed from the through via.

In this embodiment, the chemical vapor deposition process is used to form the conductive filling layer 106, and usage of a chemical vapor deposition process for forming the conductive filling layer 106 accelerates the formation rate, and is conducive to improving the formation efficiency of the semiconductor structure. In other embodiments, the conductive filling layer may be formed using an atomic layer deposition process.

The material of the conductive fill layer 106 includes a semiconductor conductive material such as doped polysilicon or polysilicon. In this embodiment, the material of the conductive filling layer 106 is doped polysilicon.

In other embodiments, referring to FIG. 14, the lower electrode film a105 located inside each mesh encircles and forms a through via. A sacrificial layer 107 fully filling the through via is formed using a chemical vapor deposition process.

The sacrificial layer 107 is configured to prevent the removal process from affecting the remaining lower electrode film a105 when the lower electrode film a105 located on the upper surface of the dielectric layer 104 and the upper surface of the upper electrode layer 103 is subsequently removed. The material of the sacrificial layer 107 is boron and phosphorus doped silicon dioxide (BPSG) or an oxygen-containing material.

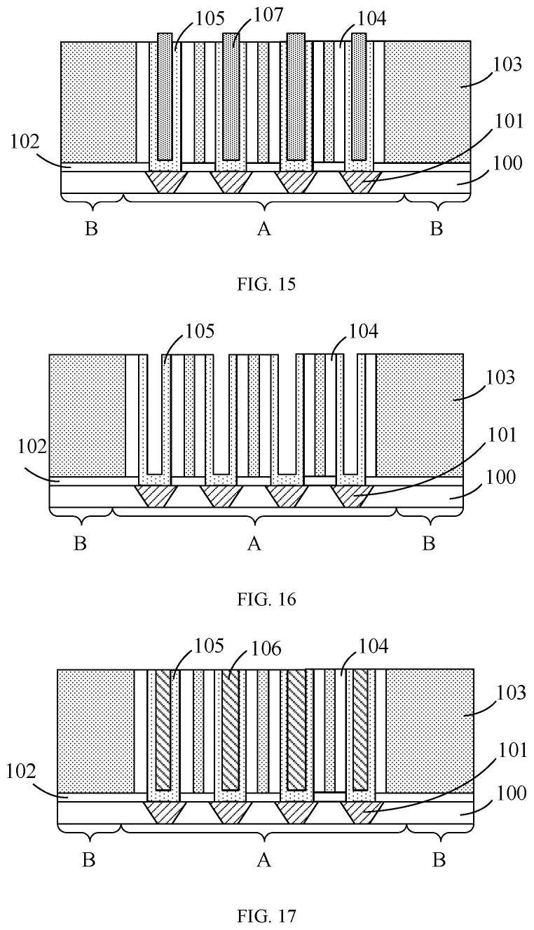

Referring to FIG. 15, after the sacrificial layer 107 is formed, the lower electrode film a105 located on the upper surface of the dielectric layer 104 and the upper surface of the upper electrode layer 103 is removed by planarization process (referring to FIG. 14), and the remaining lower electrode film a105 is the lower electrode layer 105. The formed lower electrode layer 105 is located on the side of the dielectric layer 104 away from the upper electrode layer 103 and also located on the exposed surface of the storage node contact structure 101, and the lower electrode layers 105 in different meshes are electrically insulated from each other.

The adopted planarization process is a chemical mechanical polishing process. The chemical mechanical polishing process not only removes the lower electrode film a105 located on the upper surface of the dielectric layer 104 and the upper surface of the upper electrode layer 103, so that the lower electrode layers 105 in the different meshes are electrically insulated from each other, but also makes the upper surface of the lower electrode layer 105 more flat.

Referring to FIG. 16, after the planarization process, the sacrificial layer 107 is removed by performing a targeted etching using a wet etching process (referring to FIG. 15). Due to the targeted wet etching process, there is no effect on the lower electrode layer 105 during the removal of the sacrificial layer 107.

Referring to FIG. 17, after the lower electrode layer 105 is formed, a conductive filling layer 106 is formed inside each grid, and the conductive filling layer 106 fully fills the through via, and the conductive filling layer 106 is located on the surface of the lower electrode layer 105.

In this embodiment, the chemical vapor deposition process is adopted to form the conductive filling layer 106. Usage of the chemical vapor deposition process for forming the conductive filler layer 106 accelerates the formation rate, and is conducive to improving the formation efficiency of the semiconductor structure. In other embodiments, the conductive filling layer may be formed using an atomic layer deposition process.

The material of the conductive filling layer 106 includes a semiconductor conductive material such as doped polysilicon or polysilicon. In this embodiment, the material of the conductive filling layer 106 is doped polysilicon.

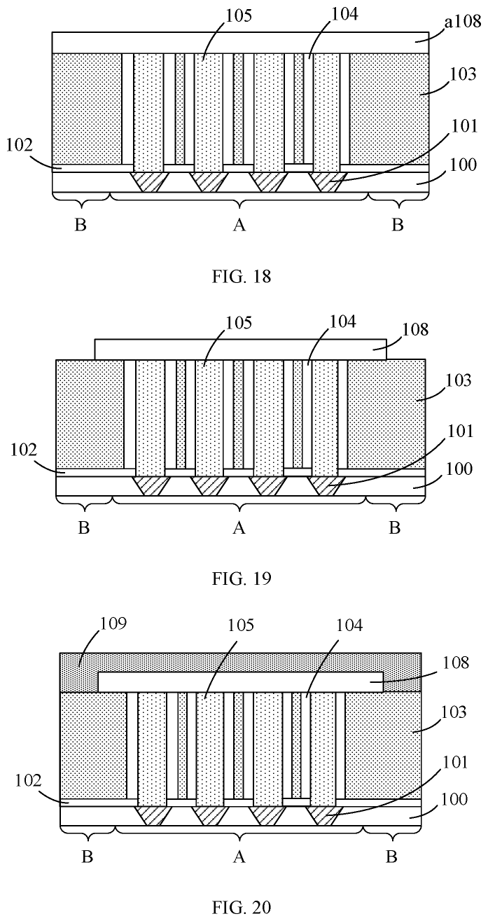

Referring to FIG. 18, in this embodiment, after the lower electrode layer 105 is formed, an initial second insulating layer a108 is formed, and the initial second insulating layer a108 is located on the upper surface of the upper electrode layer 103, the upper surface of the dielectric layer 104, and the upper surface of the lower electrode layer 105.

In this embodiment, the initial second insulating layer a108 is formed by using an atomic layer deposition process. In this embodiment, the material of the initial second insulating layer a108 is silicon oxide. In other embodiments, the material of the initial second insulating layer a108 may be a high-K material. The initial second insulating layer a108 is served as a basis for subsequent formation of the second insulating layer 108.

Referring to FIG. 19, a portion of the initial second insulating layer a108 located in the peripheral region B is removed by dry etching process (referring to FIG. 18), the remaining initial second insulating layer a108 is served as the second insulating layer 108, and the second insulating layer 108 exposes at least a portion of a surface of the upper electrode layer 103 in the peripheral region B, for facilitating electrical connection of the upper electrode layer 103 with the subsequently formed upper electrode layer filling layer.

Referring to FIG. 20, an upper electrode layer filling layer 109 is formed using an atomic layer deposition process. The upper electrode layer filling layer 109 covers the exposed at least portion of the surface of the upper electrode layer 103 in the peripheral region B, and is also located on the surface of the second insulating layer 108.

The material of the upper electrode layer filling layer 109 includes a semiconductor conductive material such as doped polysilicon and polysilicon. In this embodiment, the material of the upper electrode layer filling layer 109 is doped polysilicon.

Comparing the semiconductor structure formed by the method of the present disclosure with the semiconductor structure with the hexagonal honeycomb layout, when the bit line pitch of the semiconductor structure is 20 nm-40 nm, the word-bit line pitch ratio is 1.5, and the thicknesses of the formed dielectric layers 104 are 5.5 nm, the thickness of the upper electrode layer 103 of this embodiment is 4 nm, and the thickness of the upper electrode layer of the semiconductor structure with the hexagonal honeycomb layout is 2.5 nm. The capacitance ratio of the semiconductor structure formed in this embodiment to the semiconductor structure with the hexagonal honeycomb layout is 1.2:1, and the unit capacitance value of the semiconductor structure formed in this embodiment is increased by 20%.

In the method for forming a semiconductor structure provided in this embodiment, the grid-like upper electrode layer 103 is firstly formed, and a plurality of meshes in the upper electrode layer 103 penetrating the upper electrode layer 103 face each storage node contact structure 101. Since the grid-like upper electrode layer 103 facing the storage node contact structure 101 realizes the natural dense arrangement, the pitch ratio of the word line and the bit line does not need to be fixed, which is conducive to reducing limitations and difficulties in structural design and material requirements of the semiconductor structure. Moreover, the natural dense arrangement of the upper electrode layer 103 maximizes the area of electrode plate of the capacitor under a predetermined word-bit line pitch ratio. Since the upper electrode layer 103 is grid-like, which indicates that the upper electrode layers 103 are connected to each other and form a solid whole, the problem of the collapse of the capacitor structure is effectively avoided, and the performance of the semiconductor structure is improved.

A second embodiment of the present disclosure provides a method for forming a semiconductor structure. The method is substantially the same as the method in the first embodiment of the present disclosure, and a main difference lies in that a protective layer is formed inside the mesh before etching and removing the insulating layer exposed from the mesh. The method for forming the semiconductor structure provided in the second embodiment of the present disclosure will be described in detail below with reference to the accompanying drawings. For the portion same as or corresponding to that of the previous embodiment, please refer to the description of the above embodiment, which will not be repeated below.

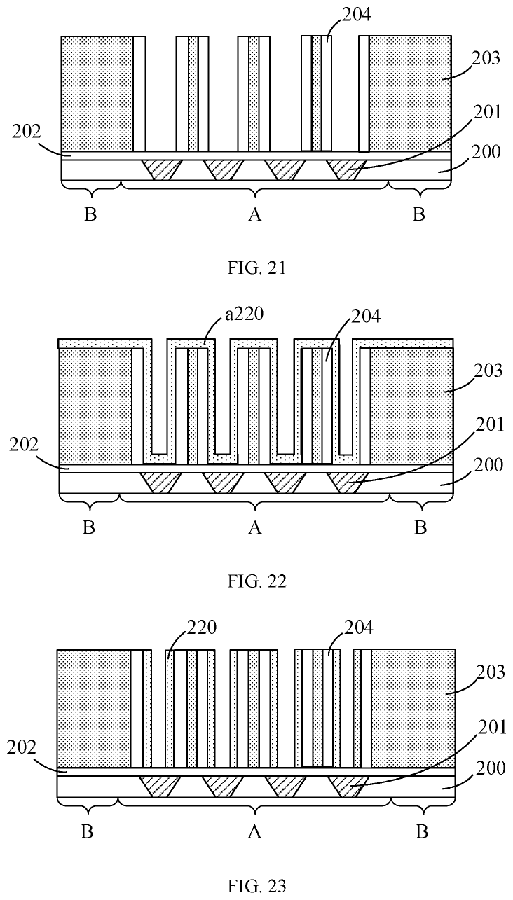

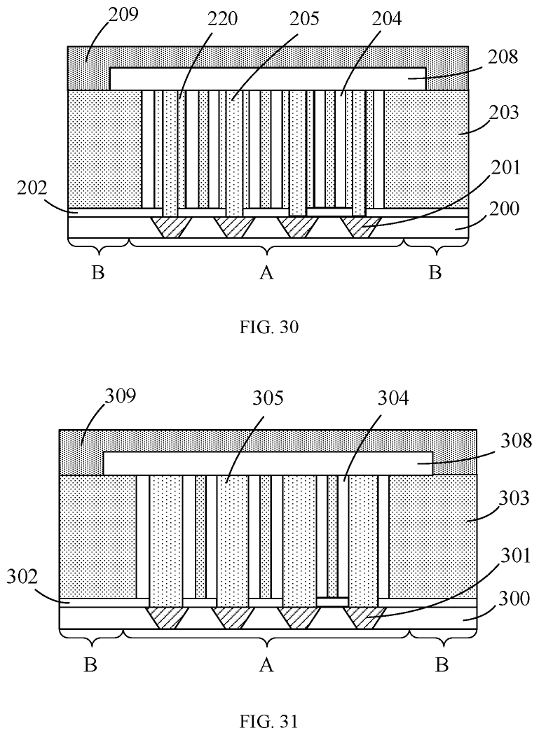

FIGS. 21-30 illustrate corresponding schematic diagrams of various steps in a method for forming a semiconductor structure according to a second embodiment of the present disclosure.

Referring to FIG. 21, in this embodiment, the formed semiconductor structure includes a capacitor region A and a peripheral region B located at the periphery of the capacitor region A. A substrate 200 and an insulating layer 202 which are stacked are provided, and the substrate 200 and the insulating layer 202 are located in the capacitor region A and the peripheral region B. The substrate 200 has a plurality of storage node contact structures 201 spaced apart from each other, and the storage node contact structures 201 are located in the capacitor region A. A grid-like upper electrode layer 203 is formed on the surface of the insulating layer 202, the upper electrode layer 203 has a plurality of meshes penetrating the upper electrode layer 203. A dielectric layer 204 is formed on the side wall of the upper electrode layer 203.

Referring to FIG. 22, a protective film a220 is formed inside the mesh using an atomic layer deposition process, and the protective film a220 is located on the side wall of the dielectric layer 204, the surface of the insulating layer 202 exposed from the mesh, the top surface of the upper electrode layer 203 and the top surface of the dielectric layer 204.

The material of the protective film a220 is a conductive material. In this embodiment, the material of the protective film a220 is the same as the material of the lower electrode layer formed subsequently, and may be specifically a titanium nitride material. In other embodiments, the material of the protective film may be doped polysilicon, titanium, titanium nitride, tungsten, tungsten composites, and the like. A protective layer is subsequently formed on the basis of the protective film a220.

Referring to FIG. 23, the protective film a220 on the surface of the insulating layer 202 exposed from the mesh, on the top surface of the upper electrode layer 203, and on the top surface of the dielectric layer 204 is removed by a dry etching process (referring to FIG. 22). The remaining protective film a220 is served as the protective layer 220, and the protective layer 220 covers the side wall of the dielectric layer 204.

As thus, when removing the insulating layer 202 exposed from the mesh, the protective layer 220 may protect the dielectric layer 204 from being affected by the removal process. Even a portion of the protective layer 220 is also removed when the insulating layer 202 is removed, since a lower electrode layer is subsequently formed in the through via formed by the protective layer 220 and the material of the lower electrode layer is the same as that of the protective layer 220, the damage to the protective layer 220 when the insulating layer 202 is removed may be compensated.

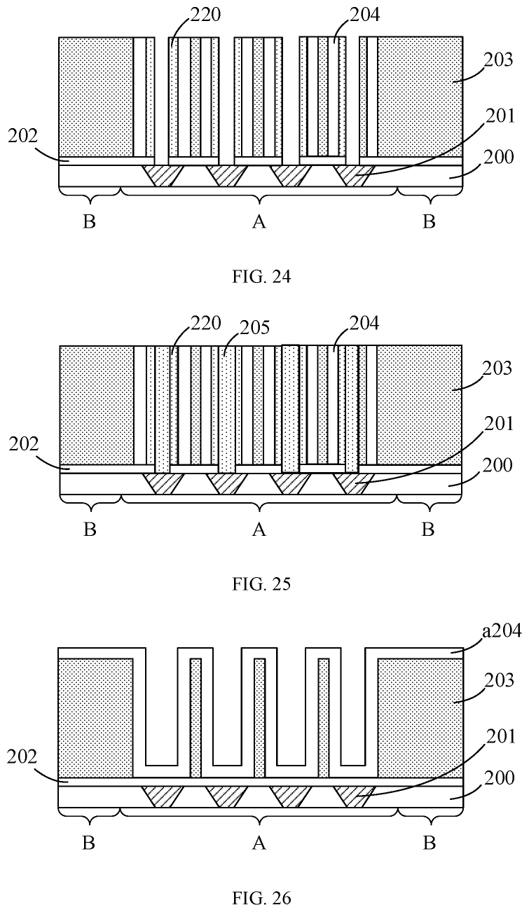

Referring to FIG. 24, the insulating layer 202 exposed from the through via is removed.

Referring to FIG. 25, a lower electrode layer 205 fully filling the through via formed by the protective layer 220 is formed, and the formed lower electrode layer 205 is located on the side wall of the protective layer 220.

Referring to FIG. 26, in other embodiments, a conformal covering dielectric film a204 is formed. Herein, the dielectric film a204 is located at the bottom and the side wall of the mesh, and also located on the upper surface of the upper electrode layer 203.

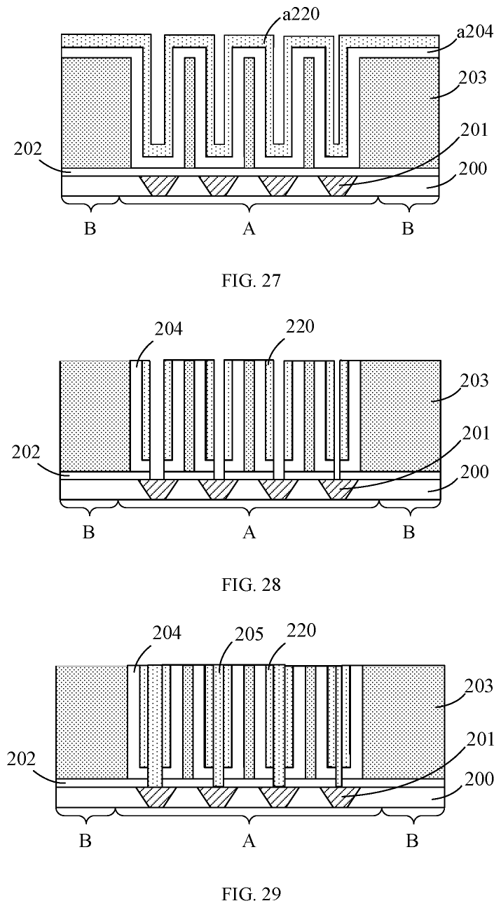

Referring to FIG. 27, a conformal covering protective film a220 is formed. Herein, the protective film a220 is located on the surface of the dielectric film a204.

Referring to FIG. 28, the protective film a220 (referring to FIG. 27) and the dielectric film a204 (referring to FIG. 27) are etched until the upper surface of the upper electrode layer 203 and the insulating layer 202 at the bottom of the mesh are exposed, and then the insulating layer 202 at the bottom of the mesh is etched and removed. The remaining protective film a220 is served as a protective layer 220, and the remaining dielectric film a204 is served as dielectric layer 204. Herein, the side wall surface of the dielectric layer 204 between the insulating layer 202 and the protective layer 220 is exposed.

Referring to FIG. 29, a lower electrode layer 205 is formed in the mesh, and the formed lower electrode layer 205 is also located on the side wall surface of the exposed dielectric layer 204.

In this embodiment, after the lower electrode layer 205 is formed, a second insulating layer 208 and an upper electrode layer filling layer 209 are formed. The details of the second insulating layer 208 and the upper electrode layer filling layer 209 are the same as those in the first embodiment, which are not described herein again.

In this embodiment, the protective layer 220 covering the side wall of the dielectric layer 204 is formed in the mesh before the insulating layer 202 exposed from the mesh is removed, so that the protective layer 220 may protect the dielectric layer 204 from being affected by the removal process when the insulating layer 202 exposed from the mesh is removed. Moreover, since the lower electrode layer 205 is subsequently required to be formed in the through via formed by the protective layer 220, and the material of the lower electrode layer 205 is the same as the material of the protective layer 220, even if a portion of the protective layer 220 is removed when the insulating layer 202 is removed, the lower electrode layer 205 of the same material can compensate for damage to the protective layer 220 when the insulating layer 202 is removed.

A third embodiment of the present disclosure provides a semiconductor structure, which may be formed by the forming method provided in the first embodiment or the second embodiment. The semiconductor structure provided in the third embodiment of the present disclosure will be described in detail below with reference to the accompanying drawings.

FIG. 31 illustrates a schematic diagram of a semiconductor structure according to a third embodiment of the present disclosure.

Referring to FIG. 31, in the present embodiment, the semiconductor structure includes a substrate 300 and an insulating layer 302 which are stacked, where the substrate 300 has a plurality of storage node contact structures 301 spaced apart from each other, and the insulating layer 302 exposes the storage node contact structures 301; a grid-like upper electrode layer 303 that is located on the surface of the insulating layer 302 and has a plurality of meshes penetrating the upper electrode layer 303, each of the meshes exposing the storage node contact structure 301; a dielectric layer 304 that is located on the side wall of each mesh; a lower electrode layer 305 that is located inside each mesh, located on the side of the dielectric layer 304 away from the upper electrode layer 303, and is also in contact with the exposed storage node contact structure 301, where the lower electrode layers 305 in different meshes are electrically insulated from each other.

In this embodiment, the semiconductor structure includes a capacitor region A and a peripheral region B located at the periphery the capacitor region A, and the substrate 300 and the insulating layer 302 are located in the capacitor region A and the peripheral region B. The material of the substrate 300 is a semiconductor material. In this embodiment, the material of the substrate 300 is silicon. In other embodiments, the substrate may also be a germanium substrate, a silicon germanium substrate, a silicon carbide substrate, or a silicon-on-insulator substrate.

In this embodiment, the storage node contact structure 301 is located in the capacitor region A, and the storage node contact structure 301 is configured to connect the transistor and the capacitor in the semiconductor structure. The material of the storage node contact structure 301 is metal. In this embodiment, the material of the storage node contact structure 301 may be tungsten metal. In other embodiments, the material of the storage node contact structure may be copper metal, aluminum metal, gold metal, silver metal, or the like.

The insulating layer 302 functions as an insulating protection. In this embodiment, the material of the insulating layer 302 is silicon oxide. In other embodiments, the material of the insulating layer 302 may be a high-K material.

The upper electrode layer 303 has a plurality of meshes penetrating the upper electrode layer 303, each of the meshes exposes a storage node contact structure 301, the meshes are located in the capacitor region A, and the upper electrode layer 303 is located not only in the capacitor region A but also in the peripheral region B.

Since word lines and bit lines of the semiconductor structure are regularly arranged in columns and rows, and a plurality of storage node contact structures 301 are arranged in a regular quadrangle, the grid-like upper electrode layer 303 facing the storage node contact structures 301 is a rectangular grid.

The upper electrode layer 303 may be a conductive material or may be composed of a plurality of conductive materials, such as doped polysilicon, titanium, titanium nitride, tungsten, and tungsten composites. In this embodiment, the upper electrode layer 303 is made of tungsten material.

Since the grid-like upper electrode layer 303 facing the storage node contact structure 301 realizes the natural dense arrangement, the pitch ratio of the word line and the bit line does not need to be fixed, which is conducive to reducing the limitations and difficulties in the structural design and material requirements of the semiconductor structure. Moreover, the natural dense arrangement of the upper electrode layer 303 maximizes the area of electrode plate of the capacitor at a predetermined word-bit line pitch ratio. Since the upper electrode layer 303 is grid-like, which indicates that the upper electrode layers 303 are connected to each other and form a solid whole, the problem of the collapse of the capacitor structure is effectively avoided.

The material of the dielectric layer 304 is a high dielectric constant material, such as high dielectric constant elements such as Hf, La, Ti, and Zr or oxides thereof, and Si and N dopants may also be used.

In this embodiment, the lower electrode layer 305 in each mesh fully fills a grid.

The lower electrode layer 305 may be a conductive material or may be composed of a plurality of conductive materials, such as doped polysilicon, titanium, titanium nitride, tungsten, and tungsten composites. In this embodiment, the lower electrode layer 305 is made of titanium nitride.

In this embodiment, the semiconductor structure further includes a second insulating layer 308, the second insulating layer 308 is located on the upper surface of the upper electrode layer 303, on the upper surface of the dielectric layer 304, and on the upper surface of the lower electrode layer 305, and exposes at least a portion of a surface of the upper electrode layer 303 in the peripheral region B, for facilitating the electrical connection of the upper electrode layer 303 with a subsequently formed upper electrode layer filling layer.

The material of the second insulating layer 308 is silicon oxide. In other embodiments, the material of the second insulating layer may be a high-K material.

This embodiment further includes an upper electrode layer filling layer 309, covering the exposed at least portion of the surface of the upper electrode layer 303 in the peripheral region B, and also located on the surface of the second insulating layer 308.

The material of the upper electrode layer filling layer 309 includes a semiconductor conductive material such as doped polysilicon and polysilicon. In this embodiment, the material of the upper electrode layer filling layer 309 is doped polysilicon.

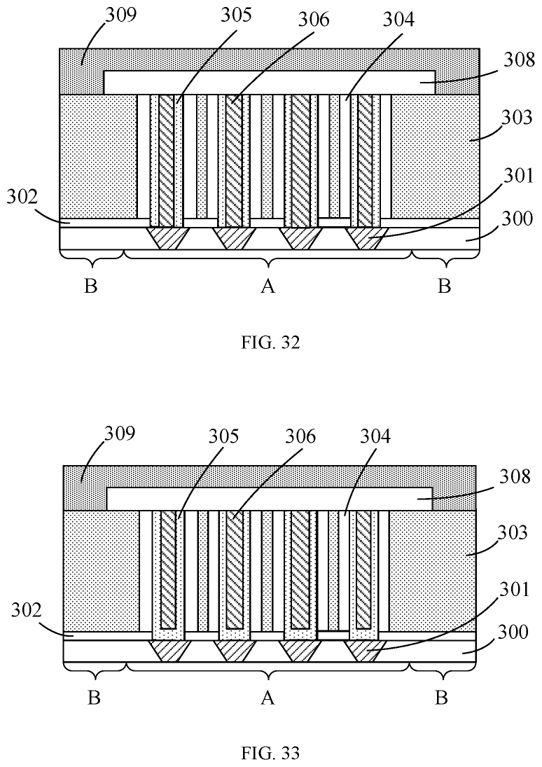

FIG. 32 illustrates a schematic diagram of another semiconductor structure according to a third embodiment of the present disclosure.

Referring to FIG. 32, in other embodiments, the lower electrode layer 305 inside each mesh encircles and forms a through via that exposes a portion of the surface of the storage node contact structure 301. The semiconductor structure further includes a conductive filling layer 306 that fully fills the through via.

The material of the conductive filling layer 306 includes a semiconductor conductive material such as doped polysilicon or polysilicon. In this embodiment, the material of the conductive filling layer 306 is doped polysilicon.

FIG. 33 illustrates a schematic diagram of still another semiconductor structure according to a third embodiment of the present disclosure.

Referring to FIG. 33, in other embodiments, the lower electrode layer 305 inside each mesh encircles and forms the through via, the lower electrode layer 305 is located on a side of the dielectric layer 304 away from the upper electrode layer 303 and also on a surface of the storage node contact structure 301. The semiconductor structure further includes a conductive filling layer 306 that fully fills the through via.

The material of the conductive filling layer 306 includes a semiconductor conductive material such as doped polysilicon or polysilicon. In this embodiment, the material of the conductive filling layer 306 is doped polysilicon.

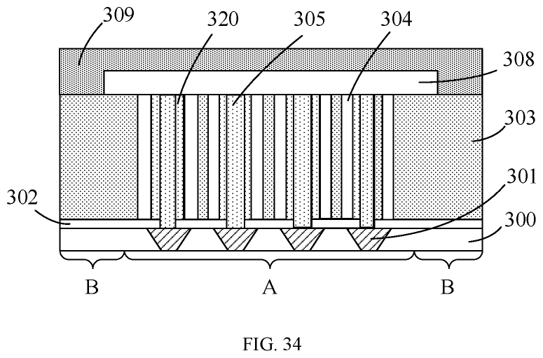

FIG. 34 illustrates a schematic diagram of yet another semiconductor structure according to a third embodiment of the present disclosure.

Referring to FIG. 34, in other embodiments, the semiconductor structure further includes a protective layer 320 that covers the side wall of the dielectric layer 304.

The material of the protective layer 320 is a conductive material. The material of the protective layer 320 is the same as that of the lower electrode layer 305, and may be specifically a titanium nitride material, doped polysilicon, titanium, titanium nitride, tungsten, and tungsten composites.

When removing the insulating layer 302 exposed from the mesh, the protective layer 320 may protect the dielectric layer 304 from being affected by the removal process. Moreover, since the lower electrode layer 305 is subsequently required to be formed in the through via formed by the protective layer 320, and the material of the lower electrode layer 305 is the same as the material of the protective layer 320, even if a portion of the protective layer 320 is removed when the insulating layer 302 is removed, the lower electrode layer 305 of the same material can compensate for damage to the protective layer 320 when the insulating layer 302 is removed.

The semiconductor structure provided in this embodiment has a grid-like upper electrode layer 303, and a plurality of meshes penetrating the upper electrode layer 303 in the upper electrode layer 303 face each storage node contact structure 301. Since the grid-like upper electrode layer 303 facing the storage node contact structure 301 realizes the natural dense arrangement, the pitch ratio of the word line and the bit line does not need to be fixed, which is conducive to reducing the limitations and difficulties in the structural design and material requirements of the semiconductor structure. Moreover, the natural dense arrangement of the upper electrode layer 303 maximizes the area of the electrode plate of the capacitor at a predetermined word-bit line pitch ratio. Since the upper electrode layer 303 is grid-like, which indicates that the upper electrode layers 303 are connected to each other and form a solid whole, the problem of the collapse of the capacitor structure is effectively avoided.

Those of ordinary skill in the art will understand that the above implementations are specific embodiments of the present disclosure, and in practical application, various changes may be made in form and details without departing from the spirit and scope of the present disclosure. Any person skilled in the art may make his own changes and modifications without departing from the spirit and scope of the present disclosure. Therefore, the protection scope of the present disclosure shall be subject to the scope limited by the claims.

What is claimed is:

1. A method for forming a semiconductor structure, comprising:
providing a substrate and an insulating layer that are stacked, wherein the substrate has a plurality of storage node contact structures spaced apart from each other;
forming a grid-like upper electrode layer on a surface of the insulating layer, wherein the upper electrode layer has a plurality of meshes penetrating the upper electrode layer, and an orthographic projection of each of the meshes on the insulating layer and an orthographic projection of the storage node contact structure on the insulating layer have an overlapping area;
forming a dielectric layer on a side wall of each mesh;
removing the insulating layer exposed from the mesh to expose the storage node contact structure; and
forming a lower electrode layer in each mesh, wherein the lower electrode layer is located on a side of the dielectric layer away from the upper electrode layer, and is also in contact with the exposed storage node contact structure, and the lower electrode layers in different meshes are electrically insulated from each other.

2. The method for forming a semiconductor structure according to claim 1, wherein steps of forming the lower electrode layer comprise: forming a lower electrode film located inside the mesh, on the side of the dielectric layer away from the upper electrode layer and on a surface of the exposed storage node contact structure, and further located on an upper surface of the dielectric layer and an upper surface of the upper electrode layer; and
removing the lower electrode film located on the upper surface of the dielectric layer and the upper surface of the upper electrode layer, wherein the remaining lower electrode film is served as the lower electrode layer.

3. The method for forming a semiconductor structure according to claim 2, wherein the lower electrode film fully fills the mesh; the lower electrode film located on the upper surface of the dielectric layer and on the upper surface of the upper electrode layer is removed by using a planarization process, and the lower electrode layer fully fills the mesh.

4. The method for forming a semiconductor structure according to claim 2, wherein the lower electrode film located in each of the meshes encircles and forms a through via; a process step of removing the lower electrode film located on the upper surface of the dielectric layer and on the upper surface of the upper electrode layer comprises:
performing dry etching on the lower electrode film, to etch and remove the lower electrode film located on the upper surface of the dielectric layer and on the upper surface of the upper electrode layer, and to further etch and remove a portion of the lower electrode film at a bottom of the through via.

5. The method for forming a semiconductor structure according to claim 2, wherein the lower electrode film located in each of the meshes encircles and forms a through via; process steps of removing the lower electrode film located on the upper surface of the dielectric layer and on the upper surface of the upper electrode layer comprise:
forming a sacrificial layer fully filling the through via;
removing the lower electrode film on the upper surface of the dielectric layer and on the upper surface of the upper electrode layer by a planarization process after forming the sacrificial layer; and
removing the sacrificial layer after the planarization process.

6. The method for forming a semiconductor structure according to claim 4, after forming the lower electrode layer, further comprising: forming, in each of the grids, a conductive filling layer that fully fills the through via.

7. The method for forming a semiconductor structure according to claim 1, wherein the insulating layer exposed from the mesh is etched and removed by a dry etching process; and
wherein the method, before the dry etching process, further comprises: forming, inside the mesh, a protective layer covering a side wall of the dielectric layer, wherein the formed lower electrode layer is also located on a side wall of the protective layer.

8. The method for forming a semiconductor structure according to claim 7, wherein process steps of forming the dielectric layer and the protective layer comprise:
forming a conformal covering dielectric film located at a bottom and the side wall of the mesh, and also located at an upper surface of the upper electrode layer;
forming a conformal covering protective film located on a surface of the dielectric film; and
etching the protective film and the dielectric film until the upper surface of the upper electrode layer and the insulating layer at the bottom of the mesh are exposed, wherein the remaining protective film is served as the protective layer and the remaining dielectric film is served as the dielectric layer; and
wherein a side wall surface of the dielectric layer located between the insulating layer and the protective layer is exposed, and the formed lower electrode layer is located on the exposed side wall surface of the dielectric layer.

9. The method for forming a semiconductor structure according to claim 7, wherein the material of the protective layer is a conductive material.

10. The method for forming a semiconductor structure according to claim 1, wherein process steps of forming the upper electrode layer comprise:
forming, on the surface of the insulating layer, a model layer having a plurality of openings penetrating the model layer;
forming the upper electrode layer that fully fills the opening; and
removing the model layer.

11. The method for forming a semiconductor structure according to claim 10, wherein the model layer is removed by a wet etching process.

12. The method for forming a semiconductor structure according to claim 1, wherein the semiconductor structure comprises a capacitor region and a peripheral region, the meshes are located in the capacitor region, and the upper electrode layer is also located in the peripheral region; the forming method further comprises:
forming a second insulating layer located on an upper surface of the upper electrode layer, on an upper surface of the dielectric layer and on an upper surface of the lower electrode layer, and exposing at least a portion of a surface of the upper electrode layer in the peripheral region; and
forming an upper electrode layer filling layer covering the exposed at least portion of the surface of the upper electrode layer in the peripheral region and located on a surface of the second insulating layer.

13. A semiconductor structure comprising:
a substrate and an insulating layer that are stacked, wherein the substrate has a plurality of storage node contact structures spaced apart from each other, and the insulating layer exposes the storage node contact structures;
a grid-like upper electrode layer located on a surface of the insulating layer and having a plurality of meshes penetrating the upper electrode layer, wherein each of the meshes exposes the storage node contact structure;
a dielectric layer located on a side wall of each mesh; and
a lower electrode layer, located inside each mesh, located on a side of the dielectric layer away from the upper electrode layer, and in contact with the exposed storage node contact structure, wherein the lower electrode layers in different meshes are electrically insulated from each other.

14. The semiconductor structure according to claim 13, wherein the lower electrode layer inside each of the meshes fully fills the grid.

15. The semiconductor structure according to claim 13, wherein the lower electrode layer inside each of the meshes encircles and forms a through via that exposes a portion of a surface of the storage node contact structure.

16. The semiconductor structure according to claim 13, wherein the lower electrode layer inside each of the meshes encircles and forms a through via, and the lower electrode layer is located on a side of the dielectric layer away from the upper electrode layer and is further located on a surface of the storage node contact structure.

17. The semiconductor structure according to claim 15, further comprising: a conductive filling layer fully filling the through via.

18. The semiconductor structure according to claim 13, comprising:
a capacitor region and a peripheral region, wherein the meshes are located in the capacitor region and the upper electrode layer is also located in the peripheral region; and
a second insulating layer, located on an upper surface of the upper electrode layer, on an upper surface of the dielectric layer and on an upper surface of the lower electrode layer, and exposing at least a portion of a surface of the upper electrode layer in the peripheral region.

19. The semiconductor structure according to claim 18, further comprising: an upper electrode layer filling layer covering the exposed at least portion of the surface of the upper electrode layer in the peripheral region, and further located on a surface of the second insulating layer.

20. The semiconductor structure according to claim 13, further comprising: a protective layer covering a side wall of the dielectric layer.
